(19) United States
(12) Patent Application Publication
(10) Pub. No.: US 2015/0325988 A1
(43) Pub. Date: Nov. 12, 2015

(54) SECTIONED CONTINUITY WIRE SYSTEM IN CONDUITS

(71) Applicant: SYNCRUDE CANADA LTD. in trust for the owners of the Syncrude Project, as such owners exist now and, Fort McMurray (CA)

(72) Inventor: SOON WON MOON, Edmonton (CA)

(73) Assignee: SYNCRUDE CANADA LTD. in trust for the owners of the Syncrude Project, as such owners exist now and, Fort McMurray (CA)

(21) Appl. No.: 14/275,405

(22) Filed: May 12, 2014

(51) Int. Cl. H02G 3/04; G01R 19/00; H01B 7/02

(52) U.S. Cl. CPC H02G 3/0462; H01B 7/0216; G01R 19/0092

(57) ABSTRACT

A conduit having an interior surface and an exterior surface and having a length (x) and an interior circumference (y) is provided, comprising: an interior liner for lining the interior surface of the conduit; and at least two independent continuity wires embedded into the interior liner, each continuity wire extending substantially the length of the conduit and each continuity wire being capable of being monitored independently; whereby each continuity wire is configured to span a portion of the conduit's interior circumference without overlapping with another continuity wire.

### FIELD OF THE INVENTION

The present invention relates to conduit systems in general and, more particularly, to a conduit and a system for sensing the deterioration of the interior of such conduits by using sectioned continuity wires.

### BACKGROUND OF THE INVENTION

The interior of conduits used to transport erosive materials such as slurries will eventually degrade due to the flow of these materials through the conduits. In general, the greatest erosion will typically occur at the six o'clock position of these conduits and, thus, these conduits are routinely rotated to expand their life span.

For example, rubber hoses are often used due to their flexibility and high wear performance. Flexible hoses are generally made of liner, reinforcement layer and cover, with the reinforcement layer sandwiched between the liner and the cover. Both liner and cover can be made of synthetic or natural rubbers, polyurethane, or the like. Other, non-flexible, conduits are also used for transporting slurries that are lined with polymeric materials, such as polyurethane, rubber, and the like, which make the conduits more abrasion resistant. However, even when using high wear performance conduits, the continuous flow of slurry will eventually cause erosion of the liner.

There is a need to be able to non-destructively test or monitor the deterioration of the interior liner of these rubber hoses or the protective linings disposed within non-rubber conduits. Generally, rubber hoses are fabricated on a mandrel, where sheets of uncured rubber are wrapped onto the mandrel to form a liner with a specified thickness, followed by wrapping reinforcement fabric layers and cover. Continuity wires are embedded in the liner by placing them between different rubber sheets. Typically, a single continuity wire is spirally wound to cover the entire body of the rubber hose. The single continuity wire can be embedded at a single liner depth or at multiple liner depths. A check point is provided, for example, an area where the wire is accessible from the surface/outside of the rubber hose, and a current is connected thereto to determine whether the current can be detected throughout the length of the rubber hose. Similarly, a single continuity wire can also be provided embedded in the liner of the non-flexible conduit.

However, there are problems associated with having a single continuity wire covering the entire body of the conduit. There is only a limited monitoring capability, i.e., only a one-time check, as once the wire breaks down in one location, the monitoring capability is lost in other locations. Thus, the prior art does not support a pipe rotation strategy, as once the wire breaks down due to wear at the six o'clock position, these rubber hoses or lined conduits lose wear monitoring capability. Thus, after a single pipe rotation, no wear monitoring capability is left.

### SUMMARY OF THE INVENTION

With a view to enabling detection of deterioration of a conduit such as a rubber hose or a conduit lined with an interior liner made from a polymeric material, the present invention provides a method and apparatus for independently monitoring different longitudinal areas of a conduit. More particularly, a conduit such as a rubber hose or a conduit lined with an interior liner made from an elastomeric polymeric material can be sectioned into separate longitudinal sections, each section having substantially the same length as the conduit but each having a width that is less that the circumference of the conduit. The number of separate sections may be decided according to the rotation strategy of a particular conduit and each section will comprise its own continuity wire.

Thus, in one aspect, a conduit having an interior surface and an exterior surface and having a length (x) and a circumference (y) is provided, comprising:

an interior liner for lining the interior surface of the conduit; and

at least two independent continuity wires embedded in the interior liner, each continuity wire extending substantially the length of the conduit and each continuity wire being capable of being monitored independently;

whereby each continuity wire is configured to span a portion of the conduit circumference without overlapping with another continuity wire.

The shape of the conduit includes, but is not limited to, a straight pipe and an elbow. The shape of the embedded wires includes, but not limited to a sinusoidal form. The continuity wire can be embedded at a single liner depth or at multiple liner depths.

In one embodiment, the conduit comprises two independent continuity wires and each continuity wire spans about half of the circumference of the conduit. This embodiment is useful when the rotation strategy is only one rotation such as in elbows. In another embodiment, the conduit comprises four independent continuity wires and each continuity wire spans about a quarter of the circumference of the conduit. This embodiment is useful when the rotation strategy is three rotations. Because each conduit section has its own continuity wire for detection of deterioration of the inside of the conduit, failure of a continuity wire in one section does not affect the monitoring capability in the other sections.

In another aspect, a system for determining the status of at least two interior sections of a conduit is provided, comprising:

a liner disposed within the conduit;

at least an equal number of independent continuity wires as there are interior sections such that each interior section has at least one continuity wire, each continuity wire embedded in the liner of its corresponding interior section and extending substantially the length of the conduit; and

a device adapted to sense and report the status of the at least two continuity wires by measuring a current through each of the at least two continuity wires.

In one embodiment, the system determines the status of two interior sections of the conduit, each section comprising about half of the circumference of the conduit. In another embodiment, the system determines the status of four interior sections of the conduit, each section comprising about a quarter of the circumference of the conduit.

### DESCRIPTION OF THE DRAWINGS

Referring to the drawings wherein like reference numerals indicate similar parts throughout the several views, several aspects of the present invention are illustrated by way of example, and not by way of limitation, in detail in the figures, wherein:

FIG. 1A is a perspective view of a conduit of the present invention which has been divided into four sections.

FIG. 1B is a cross-sectional view of the conduit of FIG. 1A.

FIG. 2 is a schematic embodiment of a system of the present invention.

### DESCRIPTION OF THE PREFERRED EMBODIMENT

The detailed description set forth below in connection with the appended drawings is intended as a description of various embodiments of the present invention and is not intended to represent the only embodiments contemplated by the inventor. The detailed description includes specific details for the purpose of providing a comprehensive understanding of the present invention. However, it will be apparent to those skilled in the art that the present invention may be practiced without these specific details.

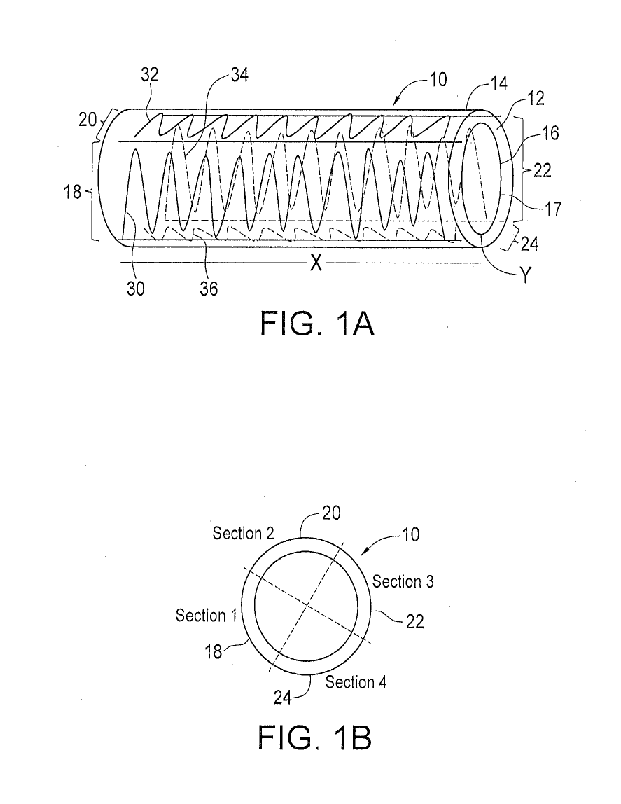

Referring to FIG. 1, there is shown one embodiment of a conduit of the present invention. Conduit 10 comprises wall 12 having an inner surface 16 and an outer surface 14, the inner surface 16 covered by a liner 17. In this particular embodiment, conduit 10 further comprises four continuity wires, 30, 32, 34 and 36, embedded into the liner 17 of the conduit 10 at four separate sections of the conduit 10, sections 18, 20, 22 and 24, respectively. In FIG. 1A, continuity wires 30, 32, 34 and 36 span most of the length (x) of the conduit 10 and span about a quarter of the inner circumference (y) without touching one another. FIG. 1B is a cross-sectional view of conduit 10 showing the four quarterly sections 18, 20, 22 and 24.

In one embodiment, conduit 10 can be a flexible hose having a liner, reinforcement layer and cover, with the reinforcement layer sandwiched between the liner and the cover. Both liner and cover are made of synthetic or natural rubbers, polyurethane, or the like. In this embodiment, the continuity wires are embedded in the liner of the flexible hose. In some embodiments, there may be multiple continuity wires embedded in each section of the flexible hose, with each wire embedded at different liner depths.

In another embodiment, conduit 10 is a non-flexible conduit made of carbon steel and the like which is lined with polymeric materials, such as polyurethane, rubber, and the like. In this embodiment, the continuity wires are embedded in the liner. In some embodiments, there may be multiple continuity wires embedded in each section at different liner depths.

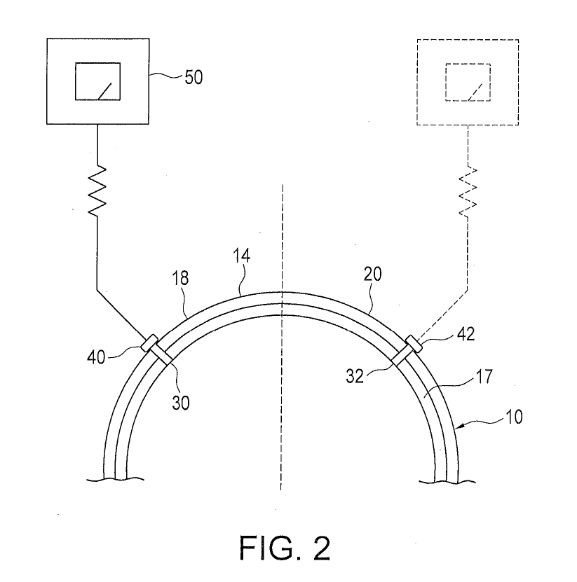

FIG. 2 illustrates an end view of a portion of conduit 10, i.e., two of the four quarter sections of FIG. 1A, namely, section 18 and section 20. As can be seen from FIG. 2, continuity wires 30 and 32, which are embedded in the liner 17, each have one end of the wire, ends 40 and 42, respectively, exposed on the outer surface 14 of conduit 10. It is understood that there also exists opposite ends of wires 30 and 32 that are exposed on the outer surface 14 of conduit 10 (not shown). Hence, an electrical current can then be transmitted across the length of each of the continuity wires 30 and 32, i.e., from one exposed end of the wire (ends 40 and 42) to the other exposed end of the wire (not shown). Ends 40 and 42 of continuity wires 18 and 20, respectively, are then connected to a current sensor 50, which detects electrical current (AC or DC) in a wire.

By way of example, conduit 10, as shown in FIGS. 1A and 1B, may first be placed on the ground with quarter section 18 at the six o'clock position, i.e., section 18 is the section closest to the ground. Because the six o'clock position of a slurry conduit is the first area which shows erosion, to test for such erosion, an electrical current is periodically run through continuity wire 30 and the electrical current thereto is detected by a current sensor. When continuity wire 30 is still intact, a current will be detected therethrough.

However, once the continuity wire is broken, due to excessive wear from the slurry, there will be no current detected through the wire. This will signal that it is likely time to rotate the conduit 90 degrees in order to avoid a potential failure in the conduit. Thus, section 20 will now be at the 6 o'clock position and continuity wire 32 will now be periodically tested to see whether continuity wire 32 is still intact. In this fashion, conduit 10 can be rotated three times and the monitoring capability of the conduit can still be maintained for each section. Hence, the life time of the conduit can be greatly enhanced without risking a failure of the conduit.

From the foregoing description, one skilled in the art can easily ascertain the essential characteristics of this invention. However, the scope of the claims should not be limited by the preferred embodiments set forth in the examples, but should be given the broadest interpretation consistent with the description as a whole.

What is claimed:

1. A conduit having an interior surface and an exterior surface and having a length (x) and an interior circumference (y), comprising:
an interior liner for lining the interior surface of the conduit; and
at least two independent continuity wires embedded in the interior liner, each continuity wire extending substantially the length of the conduit and each continuity wire being capable of being monitored independently;
whereby each continuity wire is configured to span a portion of the conduit's interior circumference without overlapping with another continuity wire.

2. The conduit as claimed in claim 1, comprising two independent continuity wires, whereby each continuity wire spans about half of the circumference of the conduit.

3. The conduit as claimed in claim 1, comprising four independent continuity wires, whereby each continuity wire spans about a quarter of the interior circumference of the conduit.

4. The conduit as claimed in claim 1, comprising continuity wires embedded at multiple liner depths.

5. A system for determining the status of at least two interior sections of a conduit, comprising:
A liner disposed within the conduit;
at least an equal number of independent continuity wires as there are interior sections such that each interior section has at least one continuity wire, each continuity wire embedded in the liner of its corresponding interior section and extending substantially the length of the conduit; and
a device adapted to sense and report the status of the at least two continuity wires by measuring a current through each of the at least two continuity wires.

6. The system as claimed in claim 5, comprising two interior sections and two continuity wires, whereby each section comprises about half of the interior circumference of the conduit and each continuity wire spans about half of the interior circumference of the conduit.

7. The system as claimed in claim 5, comprising four interior sections and four independent continuity wires, whereby each section comprises about a quarter of the interior circumference of the conduit and each continuity wire spans about a quarter of the interior circumference of the conduit.

8. The system as claimed in claim 5, comprising continuity wires embedded at multiple liner depths.
